(19) United States
(12) Patent Application Publication
(10) Pub. No.: US 2016/0154265 A1
(43) Pub. Date: Jun. 2, 2016

(54) DISPLAY PANEL, METHOD FOR MANUFACTURING DISPLAY PANEL AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Hefei (CN)

(72) Inventors: Zhenfei CAI, Beijing (CN); Guoping QIAN, Beijing (CN)

(73) Assignees: BOE TECHNOLOGY GROUP CO., LTD., Beijing (CN); HEFEI XINSHENG OPTOELECTRONICS TECHNOLOGY CO., LTD., Hefei (CN)

(21) Appl. No.: 14/797,593

(22) Filed: Jul. 13, 2015

(30) Foreign Application Priority Data
Dec. 1, 2014 (CN) 201410718535.2

(51) Int. Cl. G02F 1/1339; G02F 1/1335; G02F 1/1368; H01L 27/12

(52) U.S. Cl. CPC G02F 1/13394; H01L 27/1262; H01L 27/1218; H01L 27/1248; G02F 1/133514; G02F 1/1368

(57) ABSTRACT

The present disclosure provides a display panel, a method for manufacturing the display panel and a display device. The display panel includes a first substrate and a second substrate arranged opposite to each other. A spacer is arranged on the first substrate, and the second substrate includes a spacer supporting region. A surface of the spacer being in contact with the spacer supporting region is provided with a first clamping structure, and the spacer supporting region is provided with a second clamping structure fitted to the first clamping structure.

### CROSS-REFERENCE TO RELATED APPLICATION

The present application claims a priority of the Chinese patent application No. 201410718535.2 filed on Dec. 1, 2014, which is incorporated herein by reference in its entirety.

### TECHNICAL FIELD

The present disclosure relates to the field of display technology, in particular to a display panel, a method for manufacturing the display panel and a display device.

### BACKGROUND

During the manufacture of a liquid crystal display panel, it is required to provide a post spacer (PS) between an array substrate and a color filter substrate, so as to ensure a constant cell gap, thereby to provide a space for storing liquid crystals. Usually, the post spacer is formed at a side of the color film substrate, and a surface of the array substrate being in contact with the post spacer is flat. When the substrates expand due to being heated or are subjected to an external force, a position of the post spacer will easily be shifted, resulting in a positional shift of a color filter on the color filter substrate. As a result, an uneven color will occur to a display image of the liquid crystal display (LCD) panel.

### SUMMARY

An object of the present disclosure is to provide a display pane, a method for manufacturing the display panel and a display device, so as to prevent the occurrence of an uneven color to a display image of a liquid crystal display panel due to the movement of a spacer.

In one aspect, the present disclosure provides in one embodiment a display panel, including a first substrate and a second substrate arranged opposite to each other. A spacer is arranged on the first substrate, and the second substrate includes a spacer supporting region. A surface of the spacer being in contact with the spacer supporting region is provided with a first clamping structure, and the spacer supporting region is provided with a second clamping structure fitted to the first clamping structure.

In another aspect, the present disclosure provides in one embodiment a display device including a display panel which includes a first substrate and a second substrate arranged opposite to each other. A spacer is arranged on the first substrate, and the second substrate includes a spacer supporting region. A surface of the spacer being in contact with the spacer supporting region is provided with a first clamping structure, and the spacer supporting region is provided with a second clamping structure fitted to the first clamping structure.

Alternatively, the first clamping structure is a bulge or groove, and the second clamping structure is a groove or bulge fitted to the first clamping structure. Alternatively, the bulge is of a crisscross or X shape.

Alternatively, the first substrate is a color filter substrate, and the second substrate is an array substrate.

Alternatively, the spacer supporting region includes a convex platform on which the second clamping structure is located.

Alternatively, the convex platform includes a passivation layer and a support point pattern which is formed by a source-drain metal layer of the second substrate.

Alternatively, the convex platform is covered with a reinforcing layer pattern.

Alternatively, the reinforcing layer pattern is formed by a pixel electrode layer of the second substrate.

Alternatively, the spacer is a post spacer.

In yet another aspect, the present disclosure provides in one embodiment a method for manufacturing a display panel, including a step of providing a first substrate and a second substrate arranged opposite to each other. A spacer is arranged on the first substrate, and the second substrate includes a spacer supporting region. A surface of the spacer being in contact with the spacer supporting region is provided with a first clamping structure, and the spacer supporting region is provided with a second clamping structure fitted to the first clamping structure.

According to the embodiments of the present disclosure, the spacer may be clamped and fixed to the second substrate through the first clamping structure on the spacer being fitted to the second clamping structure on the second substrate. When the substrates expand due to being heated or the display substrate is subjected to an external pressure, a position of the spacer will not be shifted, so it is able to ensure the display quality of the display panel.

### BRIEF DESCRIPTION OF THE DRAWINGS

In order to illustrate the technical solutions of the present disclosure or the related art in a more apparent manner, the drawings desired for the present disclosure or the related art will be described briefly hereinafter. Obviously, the following drawings merely relate to some embodiments of the present disclosure, and based on these drawings, a person skilled in the art may obtain the other drawings without any creative effort.

FIG. 1 is a schematic view showing a display panel according to one embodiment of the present disclosure; and

FIG. 2 is a top view of an array substrate according to one embodiment of the present disclosure.

### DETAILED DESCRIPTION

The present disclosure will be described hereinafter in conjunction with the drawings and embodiments. The following embodiments are for illustrative purposes only, but shall not be used to limit the scope of the present disclosure.

In order to make the objects, the technical solutions and the advantages of the present disclosure more apparent, the present disclosure will be described hereinafter in a clear and complete manner in conjunction with the drawings and embodiments. Obviously, the following embodiments are merely a part of, rather than all of, the embodiments of the present disclosure, and based on these embodiments, a person skilled in the art may obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “a” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

In the following, the embodiments of the present disclosure will be described hereinafter in a clear and complete manner in conjunction with the drawings and embodiments. Obviously, the following embodiments are merely a part of, rather than all of, the embodiments of the present disclosure, and based on these embodiments, a person skilled in the art may obtain the other embodiments, which also fall within the scope of the present disclosure.

In order to prevent the occurrence of an uneven color to a display image of a display panel due to a positional shift of a spacer, the present disclosure provides in one embodiment a display panel, which includes a first substrate and a second substrate arranged opposite to each other. A spacer is arranged on the first substrate, and the second substrate includes a spacer supporting region. A surface of the spacer being in contact with the spacer supporting region is provided with a first clamping structure, and the spacer supporting region is provided with a second clamping structure fitted to the first clamping structure.

According to this embodiment, the spacer may be clamped and fixed to the second substrate through the first clamping structure on the spacer being fitted to the second clamping structure on the second substrate. When the substrates expand due to being heated or the display panel is subjected to an external pressure, a position of the spacer will not be shifted. As a result, it is able to ensure the display quality of the display panel.

Alternatively, the first clamping structure is a bulge or groove, and the second clamping structure is a groove or bulge fitted to the first clamping structure. The bulge and groove may be manufactured in a simple manner, so it is able to reduce the production cost effectively.

Alternatively, the bulge is of a crisscross shape. When the bulge of the crisscross shape is embedded into the groove being fitted, the position of the spacer will not be shifted in either an X-axis direction or a Y-axis direction in a horizontal plane. Of course, the bulge may also be of an X shape, or any other shapes.

Alternatively, the spacer supporting region includes a convex platform on which the second clamping structure is located. Through the convex platform, it is able to ensure that the spacer is of a length sufficient to support a cell gap of the display panel. In addition, in the case of an identical cell gap, it is able to reduce the length of the spacer, so that the quantity of the material being used is less and the production cost is reduced.

In the above embodiment, one of the first substrate and the second substrate is a color filter substrate, and the other one is an array substrate. The spacer may be arranged on one of the array substrate and the color filter substrate, and the spacer supporting region may be arranged on the other one of the array substrate and the color filter substrate.

Usually, the spacer is arranged on the color filter substrate, and the spacer supporting region is arranged on the array substrate, i.e., the first substrate is the color filter substrate and the second substrate is the array substrate.

Alternatively, when the first substrate is the color filter substrate and the second substrate is the array substrate, the convex platform includes a passivation layer and a support point pattern which is formed by a source-drain metal layer of the array substrate. In other words, the support point pattern may be formed together with source-drain electrodes and data lines of the array substrate by a single patterning process. As a result, it is able to reduce the number of processes desired for manufacturing the array substrate, thereby to reduce the production cost.

Alternatively, the convex platform is covered with a reinforcing layer pattern. The reinforcing layer pattern may be made of a rigid material, such as indium tin oxide (ITO), or a metal material. Through the reinforcing layer pattern, it is able to improve the strength of the second clamping structure on the convex platform.

Alternatively, the reinforcing layer pattern is formed by a pixel electrode layer of the array substrate. In other words, the reinforcing layer pattern may be formed together with a pixel electrode of the array substrate by a single patterning process. As a result, it is able to reduce the number of processes desired for manufacturing the array substrate, thereby to reduce the production cost.

In the above embodiment, the spacer may be a post spacer (PS). Of course, any other spacer may also be used alternatively.

In the following, the present disclosure will be further explained in association with the accompanying figures and the embodiments. The following embodiments are used to illustrate the present disclosure instead of limiting the protection scope thereof.

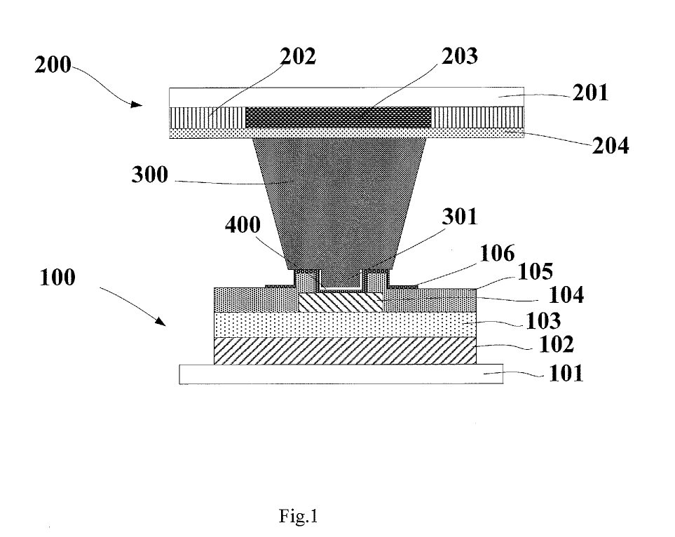

Referring to FIG. 1, which is a schematic view showing the display panel according to one embodiment of the present disclosure, the display panel includes an array substrate 100 and a color filter substrate 200 arranged opposite to each other.

The color filter substrate 200 includes a base substrate 201, and a color filter 202, a black matrix 203 and an overcoat 204 arranged on the base substrate 201. A spacer 300 is further arranged on the color filter substrate 200, and a crisscross bulge 301 is arranged at an upper end of the spacer 300. Usually, the spacer 300 is arranged on the position where the black matrix 203 is located, so as not to adversely affect the display of the display panel.

The array substrate 100 includes a base substrate 101, and gate lines 10 and data lines 20 arranged on the base substrate 101 in a crisscross manner. A plurality of pixel units (not shown) are defined by the gate lines 10 and the data lines 20, and each pixel unit includes a thin film transistor (TFT), which includes a gate electrode, a gate insulating layer, an active layer, a source electrode and a drain electrode. The gate lines 10 and the gate electrodes of the array substrate 100 are formed by an identical gate metal layer, and the data lines 20, the source electrodes and the drain electrodes of the array substrate 100 are formed by an identical source-drain metal layer.

The array substrate 100 includes a spacer supporting region, which includes the base substrate 101, the gate metal layer 102, the gate insulating layer 103, a support point pattern 104, a passivation layer 105 and a reinforcing layer pattern 106. The support point pattern 104 and the passivation layer 105 together form a convex platform. A surface of the convex platform being in contact with the spacer 300 is provided with a crisscross groove 400 being fitted to the crisscross bulge 301. The support point pattern 104 may be formed by the source-drain metal layer of the array substrate, and the reinforcing layer pattern 106 may be formed by a pixel electrode layer of the array substrate.

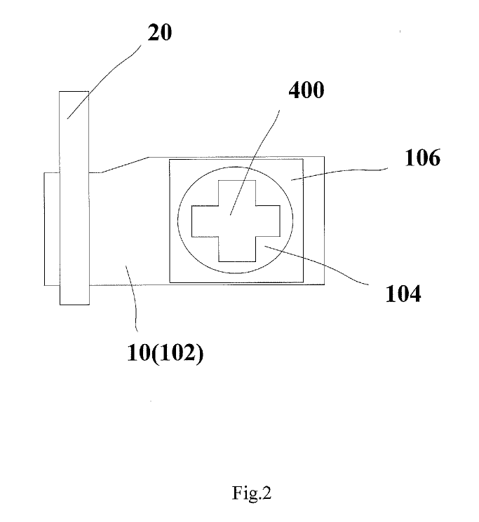

As shown in FIG. 2, the spacer supporting region may be arranged on the gate line 10, i.e., the gate metal layer 102 is just the gate line 10.

In the embodiments of the present disclosure, when the crisscross bulge 301 on the spacer 300 is embedded into the groove 400 in the array substrate 100, a position of the spacer 300 will not be shifted in either an X-axis direction or a Y-axis direction in a horizontal plane. As a result, it is able to prevent the occurrence of an uneven color to the display panel due to the positional shift of the spacer 300 after the substrates are arranged opposite to each other to form a cell.

In the above embodiments, the array substrate may be an oxide TFT array substrate, or any other TFT array substrate. When the oxide TFT array substrate is adopted for the array substrate, the spacer supporting region may further include an etch stopping layer.

The present disclosure further provides in one embodiment a display device including the above-mentioned display panel.

The present disclosure further provides in one embodiment a method for manufacturing the display panel, including a step of providing a first substrate and a second substrate arranged opposite to each other. A spacer is arranged on the first substrate, and the second substrate includes a spacer supporting region. A surface of the spacer being in contact with the spacer supporting region has a first clamping structure, and the spacer supporting region has a second clamping structure fitted to the first clamping structure.

In the above embodiment, one of the first substrate and the second substrate is a color filter substrate, and the other one is an array substrate. The spacer may be arranged on one of the array substrate and the color filter substrate, and the spacer supporting region may be arranged on the other one of the array substrate and the color filter substrate.

Usually, the spacer is arranged on the color filter substrate, and the spacer supporting region is arranged on the array substrate, i.e., the first substrate is the color filter substrate and the second substrate is the array substrate.

The method for manufacturing the display panel will be described hereinafter while it is assumed that the first substrate is the color filter substrate and the second substrate is the array substrate.

The color filter substrate may be manufactured by steps of:

(1) forming a black matrix (BM), color filters and an overcoat (OC) on a base substrate,
wherein the base substrate may be a glass substrate, a quartz substrate, or etc, and the color filters may be R, G or B color filters;

(2) applying a resin material so as to form the spacer; and

(3) forming a crisscross bulge at an upper end of the spacer by a patterning process, e.g., a half-exposure process.

The array substrate may be manufactured by steps of:

(1) forming a gate metal layer, which includes gate lines and gate electrodes, on a base substrate;

(2) forming a gate insulating layer;

(3) forming an active layer;

(4) forming a source-drain metal layer which includes source electrodes, drain electrodes, data lines and a support point pattern;

(5) forming a passivation layer which forms a convex platform in together with the support point pattern, and forming, by a patterning process, in the convex platform a crisscross groove whose size may be slightly greater than a size of the crisscross bulge on the spacer, so as to enable the crisscross bulge to be fitted into the crisscross groove conveniently; and

(6) forming a pixel electrode layer including pixel electrodes and a reinforcing layer pattern which covers the convex platform so as to reinforce the strength of the convex platform.

The above are merely the preferred embodiments of the present disclosure. It should be appreciated that, a person skilled in the art may make further modifications and improvements without departing from the principle of the present disclosure, and these modifications and improvements shall also fall within the scope of the present disclosure.

What is claimed is:

1. A display panel, comprising a first substrate and a second substrate arranged opposite to each other, wherein a spacer is arranged on the first substrate, the second substrate comprises a spacer supporting region, a surface of the spacer being in contact with the spacer supporting region is provided with a first clamping structure, and the spacer supporting region is provided with a second clamping structure fitted to the first clamping structure.

2. The display panel according to claim 1, wherein the first clamping structure is a bulge or groove, and the second clamping structure is a groove or bulge fitted to the first clamping structure.

3. The display panel according to claim 2, wherein the bulge is of a crisscross or X shape.

4. The display panel according to claim 1, wherein the first substrate is a color filter substrate, and the second substrate is an array substrate.

5. The display panel according to claim 2, wherein the first substrate is a color filter substrate, and the second substrate is an array substrate.

6. The display panel according to claim 4, wherein the spacer supporting region comprises a convex platform on which the second clamping structure is located.

7. The display panel according to claim 6, wherein the convex platform comprises a passivation layer and a support point pattern which is formed by a source-drain metal layer of the second substrate.

8. The display panel according to claim 6, wherein the convex platform is covered with a reinforcing layer pattern.

9. The display panel according to claim 8, wherein the reinforcing layer pattern is formed by a pixel electrode layer of the second substrate.

10. The display panel according to claim 1, wherein the spacer is a post spacer.

11. A display device, comprising a display device which comprises a first substrate and a second substrate arranged opposite to each other, wherein a spacer is arranged on the first substrate, the second substrate comprises a spacer supporting region, a surface of the spacer being in contact with the spacer supporting region is provided with a first clamping structure, and the spacer supporting region is provided with a second clamping structure fitted to the first clamping structure.

12. The display device according to claim 11, wherein the first clamping structure is a bulge or groove, and the second clamping structure is a groove or bulge fitted to the first clamping structure.

13. The display device according to claim 12, wherein the bulge is of a crisscross or X shape.

14. The display device according to claim 1, wherein the first substrate is a color filter substrate, and the second substrate is an array substrate.

15. The display device according to claim 14, wherein the spacer supporting region comprises a convex platform on which the second clamping structure is located.

16. The display device according to claim 15, wherein the convex platform comprises a passivation layer and a support point pattern which is formed by a source-drain metal layer of the second substrate.

17. The display device according to claim 15, wherein the convex platform is covered with a reinforcing layer pattern.

18. The display device according to claim 17, wherein the reinforcing layer pattern is formed by a pixel electrode layer of the second substrate.

19. The display device according to claim 11, wherein the spacer is a post spacer.

20. A method for manufacturing a display panel, comprising a step of providing a first substrate and a second substrate arranged opposite to each other, wherein a spacer is arranged on the first substrate, the second substrate comprises a spacer supporting region, a surface of the spacer being in contact with the spacer supporting region is provided with a first clamping structure, and the spacer supporting region is provided with a second clamping structure fitted to the first clamping structure.
